(19) United States
(12) Patent Application Publication
(10) Pub. No.: US 2024/0373601 A1
(43) Pub. Date: Nov. 7, 2024

(54) THERMAL MANAGEMENT DEVICE FOR A MODULAR PLATFORM OF AN ELECTRIC MOTOR VEHICLE CHASSIS

(71) Applicant: VALEO SYSTEMES THERMIQUES, Le Mesnil-Saint-Denis (FR)

(72) Inventors: Moussa Nacer Bey, Le Mesnil-Saint-Denis (FR); Sebastien Garnier, Le Mesnil-Saint-Denis (FR); Kamel Azzouz, Le Mesnil-Saint-Denis (FR); Amrid Mammeri, Le Mesnil-Saint-Denis (FR)

(73) Assignee: VALEO SYSTEMES THERMIQUES, Le Mesnil-Saint-Denis (FR)

(21) Appl. No.: 18/688,932

(22) PCT Filed: Jul. 29, 2022
(86) PCT No.: PCT/EP2022/071423

§ 371 Date: Mar. 4, 2024

(30) Foreign Application Priority Data
Sep. 3, 2021 (FR) FR2109228

(51) Int. Cl. H05K 7/20

(52) U.S. Cl. CPC H05K 7/20909

(57) ABSTRACT

A thermal management device for a modular platform of an electric motor vehicle chassis is disclosed. The modular platform includes batteries and an electric powertrain of the electric motor vehicle. The thermal management device includes a first module including a first heat transfer fluid circuit configured to circulate a first heat transfer fluid, a cooling module configured to have an external air flow passing through it, and a second module including a first pump and a second pump to circulate a second heat transfer fluid. The first heat transfer fluid circuit includes a compressor, a first expansion device, a multi-fluid heat exchanger, and a first heat exchanger. The cooling module includes at least a first heat exchanger configured to have the external air flow passing through it. The cooling module includes an upper side, a lower side, and first and second lateral sides opposite one another.

The present invention relates to the field of thermal management devices for electric vehicles and more particularly thermal management devices for a modular platform of an electric motor vehicle chassis.

In the automotive field and particularly in the field of electric motor vehicles, for reasons of standardization and economies of scale, modular platforms of electric motor vehicle chassis are sometimes used. Such modular platforms include in particular the batteries, the electric powertrain, as well as parts not related to the motor, in particular the wheels, and the braking and suspension system of the motor vehicle. The electric powertrain of the motor vehicle refers more specifically to the power electronics together with the electric motor(s) of the motor vehicle. Such a modular platform is used in order to have a single platform containing most of the propulsion, power supply and electrical storage components, various passenger compartments and bodies, corresponding to different models of motor vehicles, then being fitted on this platform.

However, with a view to improving the range of the electric vehicle, a large part of the space within this modular platform is reserved for the batteries. There is then little space left for the integration of a thermal management device allowing thermal management of both the batteries and the passenger compartment. Conventional thermal management devices are generally bulky and require a lot of space for their integration into a motor vehicle. These thermal management devices are thus not well suited to integration within such a modular platform.

One of the aims of the present invention is therefore to at least partially overcome the disadvantages of the prior art and to propose an improved thermal management device that can be integrated within such a modular platform.

The present invention therefore relates to a thermal management device for a modular platform of an electric motor vehicle chassis, said modular platform comprising the batteries and the electric powertrain of the electric motor vehicle, the thermal management device comprising:
a first module comprising a first heat transfer fluid circuit in which a first heat transfer fluid is intended, said first heat transfer fluid circuit comprising a compressor, a first expansion device and a multi-fluid heat exchanger and a first heat exchanger,
a cooling module being intended to have an external air flow passing through it, said cooling module comprising at least a first heat exchanger intended to have the external air flow passing through it, the cooling module comprising an upper side, a lower side, a first and a second lateral sides opposite one another, said sides forming an outer wall of the cooling module, said cooling module being intended to be integrated within the modular platform,
a second module comprising a first pump and a second pump of a second heat transfer fluid circuit in which a second heat transfer fluid is intended, said second module further comprising means for redirecting the second heat transfer fluid within said second heat transfer fluid circuit,
   characterized in that at least some of the components of the first module and of the second module are arranged on the outer wall of the cooling module.

According to one aspect of the invention, the components of the first module are grouped together on the upper side of the cooling module.

According to another aspect of the invention, the components of the second module are arranged on the same lateral side of the cooling module.

According to another aspect of the invention, the components of the second module are distributed between the two lateral sides of the cooling module.

According to another aspect of the invention, the compressor and the first heat exchanger of the first module are grouped together on the same lateral side of the cooling module.

According to another aspect of the invention, the first expansion device and the multi-fluid heat exchanger of the first module are arranged on the same lateral side as the compressor and the first heat exchanger.

According to another aspect of the invention, the first expansion device and the multi-fluid heat exchanger are arranged on a lateral side opposite the lateral side comprising the compressor and the first heat exchanger.

According to another aspect of the invention, the components of the second module are arranged on the upper side of the cooling module.

According to another aspect of the invention, the components of the second module are arranged on a lateral side of the cooling module opposite the lateral side comprising the components of the first module.

According to another aspect of the invention, the first expansion device and the multi-fluid heat exchanger are arranged in the extension of said cooling module, facing a side of said cooling module opposite the first heat exchanger.

According to another aspect of the invention, the components of the second module are distributed between:
the lateral side of the cooling module opposite the lateral side comprising the compressor and the first heat exchanger, and/or
in the extension of said cooling module, facing a side of said cooling module opposite the first heat exchanger.

The present invention also relates to a modular platform of an electric motor vehicle chassis, said modular platform comprising the batteries and the electric powertrain of the electric motor vehicle, said modular platform comprising a thermal management device as described above.

Further features and advantages of the present invention will become more clearly apparent from reading the following description, which is given by way of non-limiting illustration, and with reference to the accompanying drawings, in which:

FIG. 1 is a semi-transparent schematic view of a modular platform according to a first embodiment,

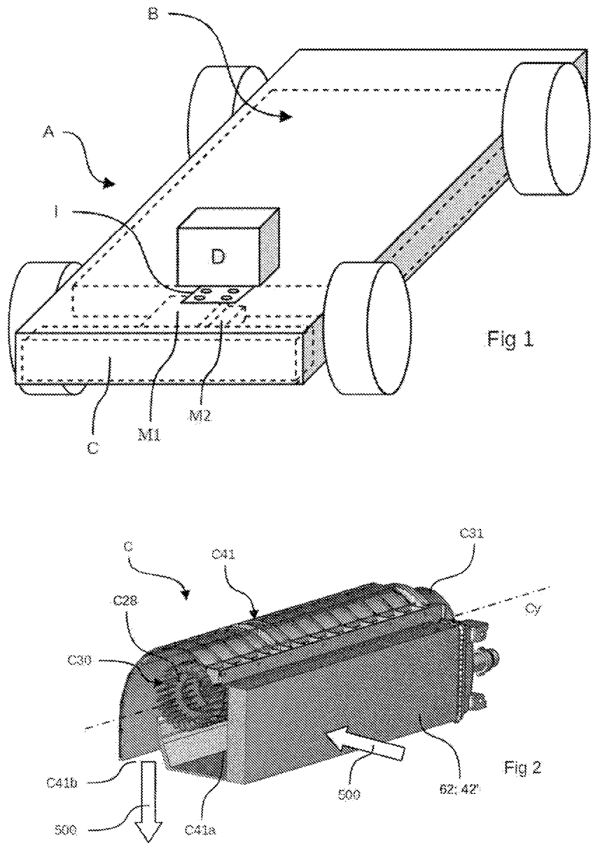

FIG. 2 is a schematic perspective view of a cooling module,

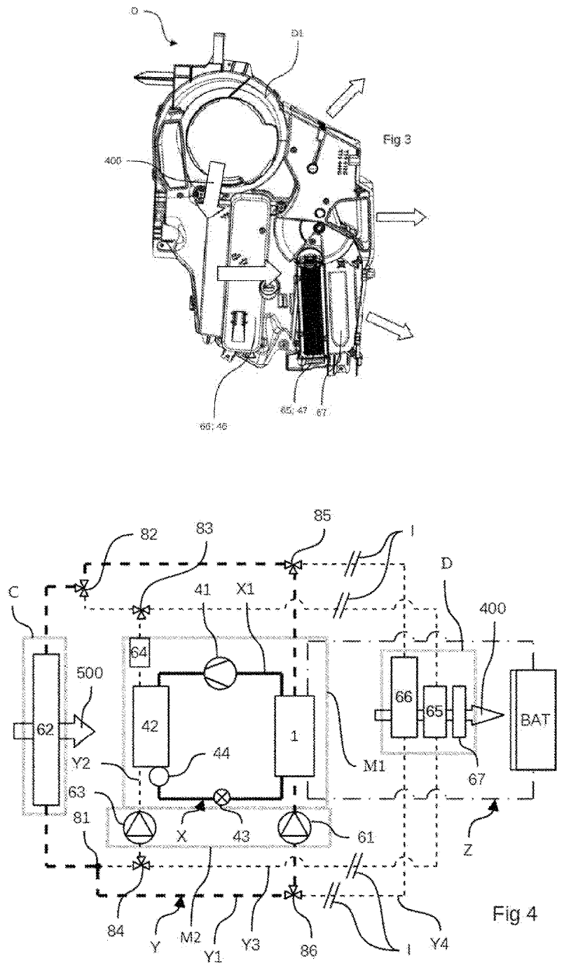

FIG. 3 is a schematic perspective view of a heating, ventilation and air-conditioning device,

FIG. 4 is a schematic view of a thermal management device according to a first example,

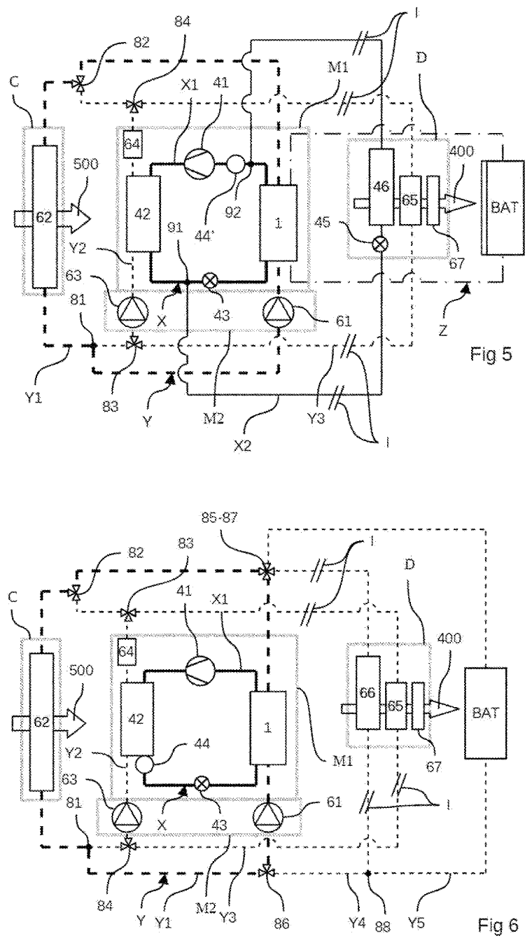

FIG. 5 is a schematic view of a thermal management device according to a second example,

FIG. 6 is a schematic view of a thermal management device according to a third example,

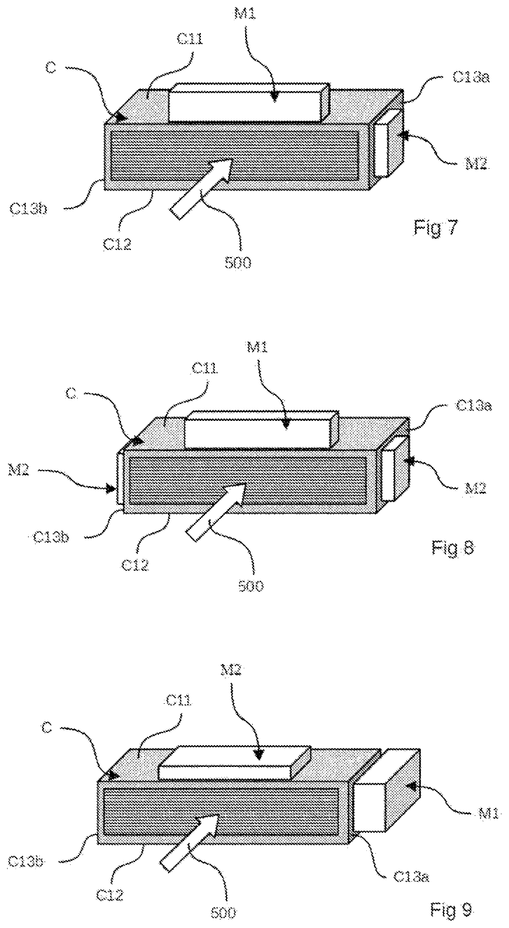

FIG. 7 is a schematic perspective view of a cooling module and the distribution of components according to a first variant of a first embodiment,

FIG. 8 is a schematic perspective view of a cooling module and the distribution of components according to a second variant of the first embodiment,

FIG. 9 is a schematic perspective view of a cooling module and the distribution of components according to a first variant of a second embodiment,

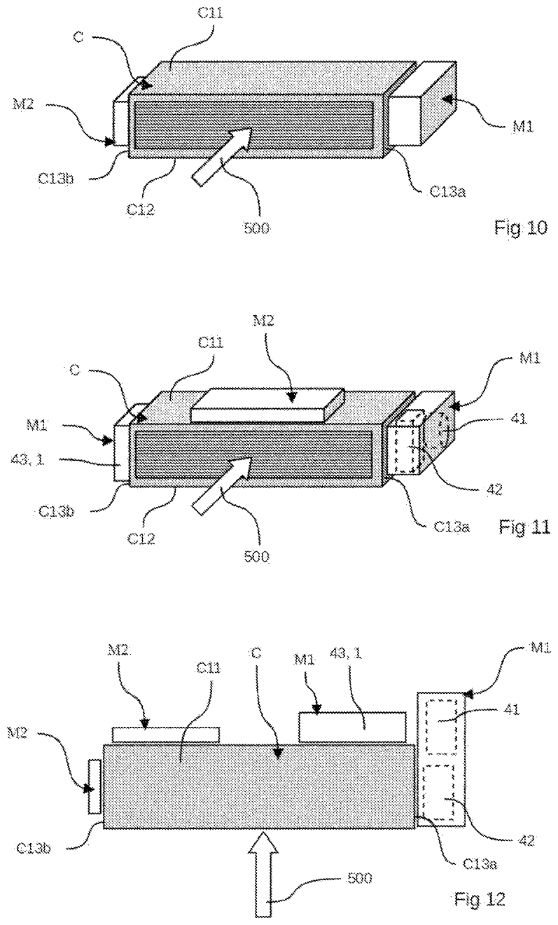

FIG. 10 is a schematic perspective view of a cooling module and the distribution of components according to an alternative of the first variant of the second embodiment,

FIG. 11 is a schematic perspective view of a cooling module and the distribution of components according to a second variant of the second embodiment,

FIG. 12 is a schematic top view of a cooling module and the distribution of components according to a third variant of the second embodiment.

In the various figures, identical elements bear the same reference numbers.

The following embodiments are examples. Although the description refers to one or more embodiments, this does not necessarily mean that each reference relates to the same embodiment, or that the features apply only to a single embodiment. Individual features of different embodiments may also be combined and/or interchanged to provide other embodiments.

In the present description, some elements or parameters may be given ordinal numbers such as, for example, first element or second element and first parameter and second parameter, or first criterion and second criterion, etc. In this case, the purpose of the ordinal numbering is simply to differentiate between and denote elements or parameters or criteria that are similar but not identical. This ordinal numbering does not imply any priority being given to one element, parameter or criterion over another and such designations may be interchanged easily without departing from the scope of the present description. Likewise, this ordinal numbering does not imply any chronological order, for example in evaluating any given criterion.

In the present description, “positioned upstream” is intended to mean that an element is positioned before another with respect to the direction in which a fluid circulates. By contrast, “positioned downstream” is intended to mean that an element is positioned after another with respect to the direction in which the fluid circulates.

FIG. 1 shows a modular platform A of an electric motor vehicle chassis. This modular platform A includes in particular the batteries B, the electric powertrain, as well as parts not related to the motor of the motor vehicle, for example the wheels, and the braking and suspension system. The electric powertrain of the motor vehicle refers more specifically to the power electronics together with the electric motor(s) of the motor vehicle. Such a modular platform A is used in particular so as to have a platform on which various passenger compartments and bodies can be fitted.

In order to allow thermal management of the batteries B and of the passenger compartment, the modular platform A includes a thermal management device comprising at least two heat transfer fluid circuits X, Y (visible in FIGS. 4, 5 and 6). The thermal management device more particularly comprises various modules fluidically connected to one another in order to form the various heat transfer fluid circuits X, Y.

The thermal management device thus comprises a first module M1 and a second module M2, which will be described in more detail below in this description.

The thermal management device further comprises a cooling module C intended to have an external air flow 500 passing through it. The cooling module C comprises in particular at least one heat exchanger 62, 42′ also intended to have the external air flow 500 passing through it. This cooling module C is intended to be integrated within the modular platform A, preferably in the front part of the modular platform.

An example of such a cooling module C is shown in particular in FIG. 2. The cooling module C may thus include a heat exchanger 62, 42′ and a first collector housing C41 attached to said heat exchanger 62, 42′. The first collector housing C41 preferably forms a volute with a first open end C41a positioned facing the heat exchanger 62, 42′ (see FIG. 2) and a second open end C41b at the opposite end of the volute.

The cooling module C may also comprise at least one tangential fan, also known as a tangential-flow turbomachine C30, which is configured such as to generate the external air flow 500, for example when the motor vehicle is stopped or at a low speed. The tangential-flow turbomachine C30 comprises a rotor or turbine (or tangential blower-wheel) C28. The turbine C28 has a substantially cylindrical shape. The turbine C28 advantageously comprises a plurality of stages of blades (or vanes). The turbine C28 is mounted rotatably about an axis of rotation Cy, for example parallel to the plane formed by the heat exchanger 62, 42′, and extending across its width. The turbine C28 is more particularly arranged within the volute formed by the first collector housing. The tangential-flow turbomachine C30 is thus compact. The use of such a tangential-flow turbomachine C30 notably makes it possible for the external air flow 500 to be equal across the entire width of the at least one heat exchanger 62, 42′. In addition, such a tangential-flow turbomachine C30 enables a space saving in comparison with conventional fans.

The tangential-flow turbomachine C30 may also comprise a motor C31 which is configured to rotate the turbine. The motor C31 is for example designed to drive the rotation of the turbine at a speed of between 200 rpm and 14 000 rpm. Such rotation speeds notably make it possible to limit the noise generated by the tangential-flow turbomachine C30.

In the example illustrated in FIG. 2, the tangential-flow turbomachine C30 is configured to operate in suction, that is to say it sucks in the ambient air such that it passes through the heat exchanger 62, 42′ and is discharged through the second open end C41b of the volute. Alternatively, the tangential turbomachine C30 may operate by discharge, that is to say blowing air from the second open end C41b of the volute toward the heat exchanger 62, 42′.

The cooling module C may also include a second collector housing (not shown) attached to the heat exchanger 62, 42′ on its face opposite that comprising the first collector housing C41. This second collector housing may include an opening to allow the external air flow 500 to pass through. This opening may have a shut-off device (not shown) that is able to move between a first position, referred to as the open position, and a second position, referred to as the shut-off position. This shut-off device is in particular configured to allow the external air flow 500 to pass through said opening in its open position and to shut off said opening in its shut-off position. The shut-off device may take various forms, such as, for example, the form of a plurality of flaps mounted so as to pivot between an open position and a closed position. These flaps are preferably mounted parallel to the width of the cooling module C. However, it is entirely possible to imagine other configurations such as, for example, flaps mounted parallel to the height of the cooling module. The flaps can be flaps of the flag type, but other types of flaps such as butterfly flaps are entirely conceivable.

The cooling module C more particularly comprises an upper side C11, a lower side C12, a first C13a and a second C13b (visible in FIGS. 7 to 12) lateral sides opposite one another. Upper side C11 in this case means the side of the cooling module C opposite the outlet C45. Lower side C12 in this case means the side of the cooling module C opposite the upper side C11 and facing the outlet C45. These various sides C11, C12, C13a, C13b more particularly form an outer wall of the cooling module C.

The thermal management device also includes a heating, ventilation and air-conditioning device D intended to have passing through it an internal air flow 400 destined for a passenger compartment. Such a heating, ventilation and air-conditioning device D is shown in FIG. 3. The heating, ventilation and air-conditioning device D comprises in particular, within a housing, a cooler 66, 46, intended to cool the internal air flow 400, a second heat exchanger 65, intended to heat the internal air flow 400, and a ventilation means DI configured to generate the internal air flow 400.

The heating, ventilation and air-conditioning device D may in particular be arranged outside the modular platform A, for example within a passenger compartment fitted on said modular platform A. In this case, the thermal management device comprises a connection interface I intended to allow the fluidic connection of the heating, ventilation and air-conditioning device D to heat transfer fluid circuits X, Y and to the elements of the thermal management device arranged within the modular platform A.

The thermal management device lastly includes an interface for heat exchange BAT with the batteries B. The heat exchange interface BAT is notably arranged within the modular platform A.

The various modules M1, M2, the cooling module C, the heating, ventilation and air-conditioning device D and the interface for heat exchange BAT with the batteries B are connected to one another in such a way as to form heat transfer fluid circuits X, Y, Z.

The use of a first module M1, a second module M2 as well as a cooling module C and a heating, ventilation and air-conditioning device D makes it possible to have a compact thermal management device that may be easily integrated within the modular platform A. In addition, the integration of several components of the first heat transfer fluid circuit X within the first module M1, and the integration of other components of the second heat transfer fluid circuit Y within the second module M2, facilitates the installation of the thermal management device within the modular platform. To be specific, these modules M1, M2 along with the cooling module C may be installed and directly connected to one another to form the thermal management device at least partially.

FIGS. 4 and 5 show various examples of thermal management devices comprising three circulation circuits each connected to a multi-fluid, in this case three-fluid, heat exchanger 1. The thermal management device thus comprises a first heat transfer fluid circuit X within which a first heat transfer fluid is intended to circulate, a second heat transfer fluid circuit Y within which a second heat transfer fluid is intended to circulate and a third heat transfer fluid circuit Z within which a third heat transfer fluid is intended to circulate.

The first module M1 more specifically comprises the first heat transfer fluid circuit X and the components of which it is composed. Within the first heat transfer fluid circuit X is intended to circulate a first heat transfer fluid, in particular a coolant, for example CO2, R134a or R1234y. The first heat transfer fluid circuit X more specifically comprises a main loop X1 including, in the direction of circulation of the coolant, a compressor 41, a first heat exchanger 42, a first expansion device 43 and the three-fluid heat exchanger 1. The first heat exchanger 42 of the first heat transfer fluid circuit X is more particularly a condenser configured to allow heat exchange between the first heat transfer fluid of the first heat transfer fluid circuit X and the second heat transfer fluid of the second heat transfer fluid circuit Y.

A second heat transfer fluid, for example water or glycol water, is intended to circulate in the second heat transfer fluid circuit Y. The second heat transfer fluid circuit Y comprises in particular a main loop Y1 comprising a first pump 61, a first heat exchanger 62, the three-fluid heat exchanger I also being connected to said main loop Y1 of the second heat transfer fluid circuit Y. This first pump 61 is in particular integrated into the second module M2.

The first heat exchanger 62 of the second heat transfer fluid circuit Y may be a radiator intended to have an external air flow 500 passing through it. The first heat exchanger 62 is then integrated within the cooling module C.

The second heat transfer fluid circuit Y comprises a first bypass branch Y2 connected to the main loop Y1 in parallel with the first heat exchanger 62 of said second heat transfer fluid circuit Y. More particularly, the first bypass branch Y2 connects a first junction point 81 to a second junction point 82. The first junction point 81 is arranged on the main loop Y1 downstream of the first heat exchanger 62, between said first heat exchanger 62 and the first pump 61. The second junction point 82 is for its part arranged on the main loop Y1 upstream of the first heat exchanger 62, between the three-fluid heat exchanger 1 and said first heat exchanger 62. Said first bypass branch Y2 may in particular comprise a second pump 63 as well as the first heat exchanger 42 of the first heat transfer fluid circuit X. This second pump 63 is more particularly integrated into the second module M2.

The first bypass branch Y2 may also include an electric heater 64 for heating the second heat transfer fluid arranged downstream of the first heat exchanger 42 of the first heat transfer fluid circuit X. This electric heater 64 may be integrated within the first module M1.

Again according to the architectures shown in FIGS. 4 and 5, the second heat transfer fluid circuit Y comprises a second bypass branch Y3 connected to the first bypass branch Y2 in parallel with the first heat exchanger 42 of the first heat transfer fluid circuit X and the second pump 63. More specifically, this second bypass branch Y3 connects a third junction point 83 to a fourth junction point 84. The third junction point 83 is arranged on the first bypass branch Y2 downstream of the first heat exchanger 42 of the first heat transfer fluid circuit X and the second pump 63, upstream of the second junction point 82. The fourth junction point 84 is for its part arranged on the first bypass branch Y2 upstream of the first heat exchanger 42 of the first heat transfer fluid circuit X and the second pump 63, downstream of the first junction point 81. The second bypass branch Y3 comprises a second heat exchanger 65 of the second heat transfer fluid circuit Y. This second heat exchanger 65 is more particularly integrated within the heating, ventilation and air-conditioning device D.

In order to control the flow of the second heat transfer fluid, the second heat transfer fluid circuit Y may include redirection means such as three-way valves arranged for example:
on the second junction point 82 so as to redirect the second heat transfer fluid coming from the three-fluid heat exchanger 1 toward the first heat exchanger 62 or the second heat exchanger 65 or so as to redirect the second heat transfer fluid coming from the third junction point 83 toward the first heat exchanger 62,
on the third junction point 83 so as to redirect the second heat transfer fluid coming from the second junction point 82 toward the second heat exchanger 65 or so as to redirect the second heat transfer fluid coming from the first heat exchanger 42 of the first heat transfer fluid circuit X toward the second junction point 82 or toward the second heat exchanger 65,
on the third junction point 83 so as to redirect the second heat transfer fluid coming from the first heat exchanger 62 or the second heat transfer fluid coming from the second heat exchanger 65 toward the first heat exchanger 42 of the first heat transfer fluid circuit X.

Other redirection means such as shut-off valves may also be considered.

These means for redirecting the second heat transfer fluid may advantageously form part of the second module M2.

In the architectures of FIGS. 4 and 5, the interface for heat exchange BAT with the batteries B is arranged within the third heat transfer fluid circuit Z in which a third heat transfer fluid, in particular a dielectric fluid, is intended to circulate. This third heat transfer fluid circuit Z is connected to the three-fluid heat exchanger 1 and the heat exchange interface BAT is a container in which the batteries are immersed at least partially and/or are subjected to vaporization of the dielectric fluid. The third heat transfer fluid circuit Z may also include a pump (not shown) in order to circulate the dielectric fluid within the heat exchange interface BAT and the circuit itself. This pump may in particular be integrated directly into the heat exchange interface BAT to save space.

The three-fluid heat exchanger 1 is more particularly configured to allow heat exchange between the second and third heat transfer fluids and the first heat transfer fluid. The use of such a three-fluid heat exchanger 1 allows, within the same heat exchanger, heat exchange both between the first heat transfer fluid and the second heat transfer fluid and between the first heat transfer fluid and the third heat transfer fluid. It is thus possible, with a single heat exchanger, to thermally couple three different circulation circuits with three different types of heat transfer fluid. The fact that these heat exchanges all take place within the same three-fluid heat exchanger 1 also allows a space saving within the motor vehicle compared to a thermal management device with three circulation circuits with a first heat exchanger specifically for heat exchange between the first heat transfer fluid and the second heat transfer fluid and a second heat exchanger specifically for heat exchange between the first heat transfer fluid and the third heat transfer fluid.

According to the architecture shown in FIG. 4, the second heat transfer fluid circuit Y may also include a third bypass branch Y4 connected to the main loop Y1 in parallel with the first pump 61 and the three-fluid heat exchanger 1. More specifically, this third bypass branch Y4 connects a fifth junction point 85 to a sixth junction point 86. The fifth junction point 85 is arranged on the main loop Y1 downstream of the three-fluid heat exchanger 1 and the first pump 61 and upstream of the second junction point 82. The sixth junction point 86 is for its part arranged on the main loop Y1 upstream of the three-fluid heat exchanger 1 and the first pump 61, and downstream of the first junction point 81. The third bypass branch Y4 includes a cooler 66 intended to have passing through it the internal air flow 400 destined for the passenger compartment. This cooler 66 is in particular integrated within a heating, ventilation and air-conditioning device D, preferably upstream of the second heat exchanger 65 in the direction of flow of the internal air flow.

In order to control the second coolant, the second heat transfer fluid circuit Y may include redirection means such as for example three-way valves arranged respectively:
on the sixth junction point 86 to redirect the second heat transfer fluid coming from the first heat exchanger 62 or coming from the cooler 66 toward the three-fluid heat exchanger 1,
on the fifth junction point 85 to redirect the second heat transfer fluid coming from the three-fluid heat exchanger 1 toward the cooler 66 or toward the second junction point 82.

Other redirection means such as shut-off valves may also be considered.

Likewise, these means for redirecting the second heat transfer fluid may advantageously form part of the second module M2.

According to this first variant, the first heat transfer fluid circuit X may also include a desiccant cartridge 44 arranged downstream of the first heat exchanger 42. This desiccant cartridge 44 may in particular be attached to the first heat transfer fluid outlet of the first heat exchanger 42. This desiccant cartridge 44 is thus integrated into the first module M1. According to another architecture shown in FIG. 5, the second heat transfer fluid circuit Y does not include a third bypass branch Y4 with a cooler 66. In this architecture shown in FIG. 5, the first heat transfer fluid circuit X includes a first bypass branch X2 connected to the main loop X1 in parallel with the first expansion device 43 and the three-fluid heat exchanger 1. This first bypass branch X1 of the first heat transfer fluid circuit X more particularly connects a first junction point 91 to a second junction point 92. The first junction point 91 is arranged on the main loop X1 upstream of the first expansion device 43, between the first heat exchanger 42 of the first heat transfer fluid circuit X and said first expansion device 43. The second junction point 92 is for its part arranged on the main loop X1 downstream of the three-fluid heat exchanger 1, between said three-fluid heat exchanger 1 and the compressor 41. This first bypass branch X2 includes a second expansion device 45 and an evaporator 46 intended to have passing through it an internal air flow 400 destined for the passenger compartment. This evaporator 46 and the second expansion device 45 are integrated within a heating, ventilation and air-conditioning device D. Preferably, the evaporator 46 is arranged upstream of the second heat exchanger 65 in the direction of flow of the internal air flow 400.

In order to control the first heat transfer fluid and allow or prevent its passage through the first bypass branch X2, the first 43 and second 45 expansion devices may be electronic expansion valves having a shut-off function. Other redirection means such as shut-off valves or three-way valves may also be considered.

According to this second variant, the first heat transfer fluid circuit X may also include an accumulator 44′ arranged upstream of the compressor 41. This accumulator 44′ may notably be arranged more specifically downstream of the second junction point 92. This accumulator 44′ is thus integrated into the first module M1.

The thermal management device may also include an electric radiator 67 placed in the internal air flow 400 destined for the passenger compartment to help heat it. This electric radiator 67 may be integrated within the heating, ventilation and air-conditioning device D, preferably furthest downstream in the direction of circulation of the internal air flow relative to the other heat exchangers of said heating, ventilation and air-conditioning device D.

FIG. 6 shows another embodiment in which the heat exchange interface BAT is for example a cold plate connected to the second heat transfer fluid circuit Y. More specifically, the heat exchange interface BAT is arranged within a fourth bypass branch Y5 of the second heat transfer fluid circuit Y connected in parallel with the first heat exchanger 62 of the second heat transfer fluid circuit Y. The multi-fluid heat exchanger 1 is therefore no longer three-fluid but simply two-fluid in this case.

In the example in FIG. 6, which is a variant of FIG. 4, the fourth bypass branch Y5 connects a seventh junction point 87 to an eighth junction point 88. The seventh junction point 87 is arranged downstream of the multi-fluid heat exchanger 1, in this case coincident with the fifth junction point 85. The eighth junction point 88 is for its part arranged downstream of the first heat exchanger 62, in this case on the third bypass branch Y4, downstream of the cooler 66. The flow of second heat transfer fluid is redirected or not toward the fourth bypass branch Y5 by a redirection means, in this case a four-way valve arranged on the fifth 85 and seventh 87 junction points. Other redirection means may of course be used, such as a set of shut-off valves. Likewise, this means for redirecting the second heat transfer fluid may advantageously form part of the second module M2.

In order to limit the bulk of the thermal management device, at least some of the components of the first module M1 and of the second module M2 are arranged on the outer wall of the cooling module C, as shown in FIGS. 7 to 12.

According to a first embodiment shown in FIGS. 7 and 8, the components of the first module M1 are grouped together on the upper side C11 of the cooling module C. The fact that these components, that is to say the compressor 41, the first expansion device 43, the multi-fluid heat exchanger 1 and the first heat exchanger 42, are placed on this upper side firstly minimizes the bulk but also allows these components to be protected from any projectiles or impacts that may come from the underbody of the motor vehicle.

According to a first variant of this first embodiment shown in FIG. 7, the components of the second module M2 may be arranged on the same lateral side C13a, C13b of the cooling module C. The first pump 61, the second pump 63 as well as the various valves of the means for redirecting the second heat transfer fluid are thus all grouped together on the same lateral side C13a, C13b.

According to a first variant of this first embodiment shown in FIG. 8, the components of the second module M2 are distributed between the two lateral sides C13a, C13b of the cooling module C. For example, the first 61 and the second 62 pumps may be arranged on the first lateral side C13a with in particular the redirection means of the fourth 84 and sixth 86 junction points. The redirection means of the second 82, third 83, fifth 85 and possibly seventh 87 junction points may for their part be arranged on the second lateral side C13b.

FIGS. 9 to 12 show a second embodiment in which the compressor 41 and the first heat exchanger 42 of the first module M1 are grouped together on the same lateral side C13a, C13b of the cooling module C.

According to a first variant of this second embodiment shown in FIGS. 9 and 10, the first expansion device 43 and the multi-fluid heat exchanger 1 are arranged on the same lateral side C13a, C13b as the compressor 41 and the first heat exchanger 42. In the example shown in FIG. 9, the components of the second module M2 are arranged on the upper side C11 of the cooling module C. In the example shown in FIG. 10, the components of the second module M2 are arranged on a lateral side C13a, C13b of the cooling module C opposite the lateral side C13a, C13b comprising the compressor 41 and the first heat exchanger 42.

According to a second variant of the second embodiment shown in FIG. 11, the first expansion device 43 and the multi-fluid heat exchanger 1 are arranged on a lateral side C13a, C13b opposite the lateral side C13a, C13b comprising the compressor 41 and the first heat exchanger 42. The first module M1 is thus distributed on the two lateral sides C13a, C13b of the cooling module C. According to this second variant, the components of the second module M2 are arranged on the upper side C11 of the cooling module C.

FIG. 12 shows a third variant of the second embodiment in which the first expansion device 43 and the multi-fluid heat exchanger 1 are arranged in the extension of said cooling module C, facing a side of said cooling module C opposite the first heat exchanger 62. This makes it possible in particular to limit the increase in the width of the thermal management device by limiting the number of components arranged on the lateral sides C13a, C13b of the cooling module C. According to this third variant, the components of the second module M2 may also be distributed between:
a lateral side C13a, C13b of the cooling module C opposite the lateral side C13a, C13b comprising the compressor 41 and the first heat exchanger 42, and/or
the rear of the cooling module C in the extension of said cooling module C.

For example, the first 61 and the second 63 pumps as well as the redirection means of the fourth 84 and sixth 86 junction points may be arranged on a lateral side C13a, C13b of the cooling module C opposite the lateral side C13a, C13b comprising the compressor 41 and the first heat exchanger 42. The redirection means of the second 82, third 83, fifth 85 and possibly seventh 87 junction points may for their part be arranged in the extension of said cooling module C, facing a side of said cooling module C opposite the first heat exchanger 62.

Preferably, in this third variant, the components of the first M1 and of the second M2 module are arranged facing the side of the cooling module C opposite the first heat exchanger 62 in such a way as not to hinder the discharge of the external air flow 500. To this end, these components are preferably offset relative to the outlet C31 of the cooling module C.

It is thus clear that placing the components of the first module M1 and of the second module M2 on the periphery of the cooling module C makes it possible to limit the bulk of the thermal management device and facilitates its integration within a modular platform A.

1. A thermal management device for a modular platform of an electric motor vehicle chassis,
the modular platform comprising batteries and an electric powertrain of the electric motor vehicle,
the thermal management device comprising:
a first module comprising a first heat transfer fluid circuit which is configured to circulate a first heat transfer fluid,
the first heat transfer fluid circuit comprising a compressor, a first expansion device, a multi-fluid heat exchanger and a first heat exchanger,
a cooling module configured to have an external air flow passing through it,
the cooling module comprising at least a first heat exchanger configured to have the external air flow passing through it,
the cooling module comprising an upper side, a lower side, a first and a second lateral sides opposite one another,
wherein the sides form an outer wall of the cooling module,
wherein the cooling module is configured to be integrated within the modular platform, and
a second module comprising a first pump and a second pump of a second heat transfer fluid circuit in which a second heat transfer fluid is circulated,
the second module further comprising means for redirecting the second heat transfer fluid within the second heat transfer fluid circuit,
wherein at least some of the components of the first module and of the second module are arranged on the outer wall of the cooling module.

2. The thermal management device as claimed in claim 1,
wherein the components of the first module are grouped together on the upper side of the cooling module.

3. The thermal management device as claimed in claim 2,
wherein the components of the second module are arranged on the same lateral side of the cooling module.

4. The thermal management device as claimed in claim 2,
wherein the components of the second module are distributed between the two lateral sides of the cooling module.

5. The thermal management device as claimed in claim 1,
wherein the compressor and the first heat exchanger of the first module are grouped together on the same lateral side of the cooling module.

6. The thermal management device as claimed in claim 5,
wherein the first expansion device and the multi-fluid heat exchanger of the first module are arranged on the same lateral side as the compressor and the first heat exchanger of the first module.

7. The thermal management device as claimed in claim 5,
wherein the first expansion device and the multi-fluid heat exchanger are arranged on a lateral side opposite the lateral side comprising the compressor and the first heat exchanger of the first module.

8. The thermal management device as claimed in claim 6,
wherein the components of the second module are arranged on the upper side of the cooling module.

9. The thermal management device as claimed in claim 6,
wherein the components of the second module are arranged on a lateral side of the cooling module opposite the lateral side comprising the components of the first module.

10. The thermal management device as claimed in claim 5,
wherein the first expansion device and the multi-fluid heat exchanger are arranged in the extension of the cooling module, facing a side of the cooling module opposite the first heat exchanger of the cooling module.

11. The thermal management device as claimed in claim 10,
wherein the components of the second module are distributed between:
the lateral side of the cooling module opposite the lateral side comprising the compressor and the first heat exchanger of the first module, and
in the extension of the cooling module, facing a side of the cooling module opposite the first heat exchanger of the cooling module.

12. A modular platform of an electric motor vehicle chassis,
the modular platform comprising the batteries and the electric powertrain of the electric motor vehicle, wherein the modular platform comprises a thermal management device as claimed in claim 1.
